(19) United States
(12) Patent Application Publication
(10) Pub. No.: US 2023/0157181 A1
(43) Pub. Date: May 18, 2023

(54) EMBEDDED MAGNETORESISTIVE RANDOM ACCESS MEMORY TOP ELECTRODE STRUCTURE

(71) Applicant: International Business Machines Corporation, Armonk, NY (US)

(72) Inventors: Ashim Dutta, Clifton Park, NY (US); Chih-Chao Yang, Glenmont, NY (US)

(21) Appl. No.: 17/455,226

(22) Filed: Nov. 17, 2021

(51) Int. Cl. H01L 43/02; H01L 27/22; H01L 43/12

(52) U.S. Cl. CPC H01L 43/02; H01L 27/222; H01L 43/12

(57) ABSTRACT

An approach to provide a pillar-type memory device with a bump of a conductive material on a top electrode of the pillar-type memory device. The top electrode is composed of a thin layer of the top electrode material. The bump of the conductive material increases the height of the top electrode after pillar formation for the pillar-type memory device. The pillar-type memory device includes the bump of the conductive material with a semi-sphere-like bump of the conductive metal that is slightly wider than the top electrode of the pillar-type memory device. A contact connects with the bump of the conductive material on the top electrode.

### BACKGROUND OF THE INVENTION

The present invention relates generally to the field of semiconductor memory device technology and more particularly to magnetoresistive random-access memory devices.

Increasing computing function today requires both more device circuits and faster processing speeds for computer systems and applications. In particular, the use of deep neural networks is becoming pervasive in many end-use computer applications. Deep neural networks are typically used in artificial intelligence (AI) applications. The training of deep neural networks puts significant demand on the memory systems in computer systems executing AI applications with deep neural networks. Increasing demand for high-performance memory systems continues to drive the development of new and advanced memory devices in memory chips.

Non-volatile memory (NVM) or non-volatile storage is a type of computer memory that can retain stored information even after power is removed. Non-volatile memory typically refers to storage in semiconductor memory chips which typically store data in floating-gate memory cells consisting of floating-gatemetal-oxide-semiconductor field-effect transistors (MOSFETs), including flash memory storage such as NAND flash and solid-state drives (SSD).

Developments in advanced memory devices for NVM include several new technology developments in NVM memory devices. Magnetoresistive random-access memory (MRAM) is a type of non-volatile random-access memory that stores data in magnetic domains using magnetic tunnel junctions formed with multiple thin layers of magnetic and non-magnetic stacked materials as discussed below in more detail. Resistive random-access memory (RRAM or ReRAM) devices work by changing the resistance across a dielectric solid-state material. Phase change random-access memory (PCRAM or PCM) uses phase change materials, which typically have at least two phases, a crystalline phase, and an amorphous phase, with very different electrical properties for set and re-set states to store and retrieve data.

The demand for high-performance memory systems in current computer applications also drives an increasing density of memory devices. Decreasing the pitch, or space between memory devices increases the number of available memory devices in a memory chip and increases memory chip performance. Many emerging NVM memory devices are being formed with vertical structures or pillars in pursuit of increasing memory device density.

Magnetoresistive Random Access Memory (MRAM), based on the integration of silicon-based complementary silicon-oxide semiconductor (CMOS) with magnetic tunnel junction (MTJ) technology, is now a promising non-volatile memory technology using vertical structures or pillars. MRAM technology provides many advantages in terms of writing/read speed, power consumption, and lifetime over other commercialized memory types including SRAM, DRAM, Flash, etc. Conventional MRAM devices include a magnetic tunnel junction (MTJ) structure having magnetic layers separated by an intermediary non-magnetic tunnel barrier layer. Digital information can be stored in the memory element and can be represented by directions of magnetization vectors. In response to the current applied to the MTJ, the magnetic memory element exhibits different resistance values and allows an MRAM device to provide information stored in the magnetic memory element. Typically, MRAM devices may be fabricated with a field-effect transistor (FET) which can access the MRAM device.

### SUMMARY

Embodiments of the present invention provide a pillar-type memory device. The pillar-type memory device includes a bump of a conductive material on a top electrode of the pillar-type memory device, where the top electrode is a thin top electrode, and the bump of the conductive material increases the height of the top electrode. Embodiments of the present invention include the bump of the conductive material is a semi-spherelike bump of the conductive metal that is slightly wider than the top electrode of the pillar-type memory device. A contact connects with the bump of the conductive material on the top electrode.

Embodiments of the present invention include a plurality of pillar-type memory devices in an array. Each of the pillar-type memory devices in the array has a semi-spherical-like bump of the conductive material on a top electrode of each of the pillar type-memory devices in the array, where the top electrode is a thin top electrode. Each of the pillar-type memory devices in the array includes an encapsulation dielectric material that covers the sidewalls of each of the plurality of memory devices in the array but does not cover the semi-spherical bump of the conductive material. A self-leveling dielectric material is between the bottom the portions of the encapsulation material. A layer of an interlayer dielectric material is over the self-leveling dielectric material and between the semi-spherical-like bump of the conductive material on a top electrode of the pillar type-memory devices. A contact connects with the bump of the conductive material on the top electrode in each of the pillar-type memory devices in the array of pillar-type memory devices.

Embodiments of the present invention include a plurality of pillar-type memory devices in an array. Each of the pillar-type memory devices in an array of pillar-type memory devices has a bump of the conductive material on a top electrode of each of the pillar type-memory devices in the array, a first encapsulation dielectric material covers the sidewalls each of the plurality of memory devices in the array of pillar-type memory devices, and a second encapsulation material is over the first encapsulation material and a bottom portion of the bump of the conductive material. The second encapsulation material creates a v-like gap between adjacent pillars in the array of the pillar-type memory devices. The second encapsulation material improves the ability of the interlayer dielectric material to fill the gap between adjacent pillars. The array of the plurality of pillar-type memory devices includes an interlayer dielectric material that is over the second encapsulation material and between the bump of the conductive material on a top electrode of each of the pillar type-memory devices. The second encapsulation material is between each of the pillar-type memory devices in the array. A contact connects with the bump of the conductive material on the top electrode in each of the pillar-type memory devices in the plurality of pillar-type memory devices.

Embodiments of the present invention include a method of forming a pillar-type memory device in an array of pillar-type memory devices. The method includes depositing a plurality of layers of materials for forming a pillar for a plurality of pillar-type memory devices, wherein a layer of a top electrode material in the plurality of material is a thin layer of the top electrode material with a semi-spherical-like bump of pillar-type a high melting point metal or a metal nitride material on the top surface of the top electrode material to form a conductive bump on the top electrode material. The method includes the following processes and steps.

Embodiments of the present invention provide a method of forming a pillar-type memory device in an array of pillar-type memory devices. The method includes depositing a plurality of layers of materials for forming a pillar for a plurality of pillar-type memory devices in an array of pillar-type devices, where a layer of the top electrode material in the plurality of material is a thin layer of the top electrode material. The method includes patterning the top electrode material and using an ion beam etch to form each pillar of the plurality of pillar-type memory devices from the plurality of layers of materials. The method includes depositing a layer of the first encapsulation material and etching back the layer of the first encapsulation material to expose a top surface of the top electrode material.

The method includes selectively depositing one of a high melting point metal or a metal nitride material on the exposed top surface of the top electrode material to form a conductive bump on the top electrode material. The method includes depositing a layer of a second encapsulation material over the first encapsulation material, over an exposed portion of a dielectric material that is between each pillar of the plurality of pillar-type memory devices and surrounding a bottom portion of the conductive bump on the top electrode. The method includes etching back the layer of the second encapsulation material to expose a top surface of the conductive bump and depositing an interlayer dielectric material over exposed surfaces of the conductive bump, the second encapsulation material, and the dielectric material between each pillar of the plurality of pillar-type memory devices. Embodiments of the present invention include forming an array of pillar-type memory devices where each of the pillar-type memory devices are one of an MRAM, a PCRAM, or an RRAM device.

### BRIEF DESCRIPTION OF THE DRAWINGS

The above and other aspects, features, and advantages of various embodiments of the present invention will be more apparent from the following description taken in conjunction with the accompanying drawings.

FIG. 1 is a cross-sectional view of a semiconductor structure after depositing one or layers of lithographic material over a layer of electrode material for a magnetoresistive random access memory (MRAM) device in accordance with an embodiment of the present invention.

FIG. 2 is a cross-sectional view of the semiconductor structure after patterning and etching portions of the lithographic materials and the electrode material in accordance with an embodiment of the present invention.

FIG. 3 is a cross-sectional view of the semiconductor structure after etching the MRAM stack, the bottom electrode, and removing a layer of hardmask over the MRAM stack in accordance with an embodiment of the present invention.

FIG. 4 is a cross-sectional view of the semiconductor structure after depositing an encapsulating dielectric material and etching back a portion of the encapsulating dielectric material in accordance with an embodiment of the present invention.

FIG. 5 is a cross-sectional view of the semiconductor structure after depositing a dielectric material between the MRAM pillars and over the logic device area in accordance with an embodiment of the present invention.

FIG. 6 is a cross-sectional view of the semiconductor structure after selectively depositing an additional metal material over the top electrode in accordance with an embodiment of the present invention.

FIG. 7 is a cross-sectional view of the semiconductor structure after depositing a layer of an interlayer dielectric material in accordance with an embodiment of the present invention.

FIG. 8 is a cross-sectional view of the semiconductor structure after forming vias, contacts, and lines in a metal layer above the MRAM device in accordance with an embodiment of the present invention.

FIG. 9 is a cross-sectional view of a semiconductor structure after selectively depositing an additional metal material over the top electrode of the MRAM pillar depicted in FIG. 4 in accordance with a second embodiment of the present invention.

FIG. 10 is a cross-sectional view of the semiconductor structure after depositing a second layer of the encapsulating material in accordance with the second embodiment of the present invention.

FIG. 11 is a cross-sectional view of the semiconductor structure after etching back the second encapsulating material and depositing a dielectric material in accordance with the second embodiment of the present invention.

FIG. 12 is a cross-sectional view of a semiconductor structure after depositing another metal layer and forming vias and contacts in accordance with the second embodiment of the present invention.

FIG. 13 is an example of a method of forming an array of embedded pillar-type memory devices with a thinner top electrode and an additional electrode metal selectively deposited on the thinner top electrode in accordance with an embodiment of the present invention.

### DETAILED DESCRIPTION

Embodiments of the present invention recognize that conventional structures and methods of forming dense arrays of pillar-type memory devices are desired to meet the increasing memory demands of artificial intelligence and other high-performance computer system requirements. Embodiments of the present invention recognize that as device feature sizes decrease and memory device pitch reduces, the height of the pillars forming the memory devices in the array of memory devices is becoming more problematic during memory device formation. With decreasing memory device pitch, shadowing of adjacent pillars during ion beam etching processes used to create the pillars that form each pillar-type memory device in an array of memory devices occurs. The shadowing occurring during the ion beam etch creates difficulties in providing clean pillar sidewalls after the ion beam etch. Embodiments of the present invention, therefore, recognize that lower pillar heights provide potential benefits in the fabrication process. Specifically, a method and a semiconductor structure providing a lower pillar height during ion beam etch to reduce shadowing of adjacent pillars in memory device pillar formation would improve pillar sidewall surface cleanliness after ion beam etch and reduce yield loss due to material residue on pillar sidewalls after the ion beam etch.

Embodiments of the present invention also recognize that a lower pillar height may include some challenges in contact formation. For example, a tall top electrode in a taller pillar of a pillar-type memory device provides the benefit of preventing electrical shorting between the top electrode contacts and the magnetic tunnel junction (MTJ) in pillar-type memory devices. Embodiments of the present invention recognize that it would be desirable to provide a lower memory device pillar for the ion beam etch that forms the array of memory pillars while providing a taller pillar to reduce top electrode contact shorting to active elements, such as MTJs in the pillar-type memory devices. Embodiments of the present invention recognize the desirability of a lower top surface of the top electrode material during ion beam etch, and a taller top electrode after ion beam etch.

Additionally, embodiments of the present invention recognize that with tall pillars of the pillar-type memory devices and decreasing memory device pitch in memory arrays, an interlayer dielectric (ILD) fill between the tightly pitched memory pillars in an array of memory pillars is becoming more challenging. For closely packed memory pillars, the gaps between adjacent pillars do not always uniformly fill with ILD material. Embodiments of the present invention recognize that uneven surfaces in the ILD between pillars may create voids in the surface of the ILD material. These uneven surfaces or voids can allow the conductive metal to settle in unwanted locations during top electrode contact formation processes. The captured or smeared conductive contact metal after top electrode contact formation can create electrical shorts between some of the adjacent top electrode contacts in the array of pillar-type memory devices. Embodiments of the present invention recognize that providing a more level ILD surface during top electrode contact formation would reduce yield loss and prevent shorting between adjacent top electrode contacts in an array of pillar-type memory devices.

Embodiments of the present invention provide a structure and a method of forming an array of pillar-type memory devices where the top electrode material is thinner than conventionally deposited top electrode material, and an additional conductive metal material is selectively deposited over the thinner top electrode material to provide a taller pillar for the memory device during contact formation. The thinner top electrode material provides a shorter pillar formed by the ion beam etch. With a thinner top electrode, the stack of materials forming the pillar of a pillar-type memory device is lower. The lower stack of materials (i.e., with a thinner layer of the top electrode material) will cause less shadowing during ion beam etch. Embodiments of the present invention with the lower pillar height during ion beam etching provide better pillar etch, with cleaner pillar sidewalls after ion beam etching that results in improved pillar-type memory device yields. The methods and structures disclosed are discussed with reference to pillar-type MRAM devices however, the structures disclosed herein are not limited to pillar-type MRAM devices but are applicable to other pillar-type non-volatile memory devices such as PCRAM and RRAM devices.

Embodiments of the present invention also provide a structure and a method of increasing the effective height of the shorter pillars by selectively depositing a bump or semi-spherical-like shaped portion of the conductive material on the top surface of the top electrode after ion beam etch and before the top electrode contact formation. The bump of conductive material deposited on the thinner top electrode material effectively increases the height of the top electrodes prior to top electrode contact formation. The taller top electrodes in the pillar-type memory devices reduce electrical shorts that can occur between active elements in the pillar-type memory devices, such as shorts to the MTJ during top electrode contact formation.

Additionally, embodiments of the present invention provide better interlayer dielectric fill between dense, tightly packed pillar-type memory devices. Embodiments of the present invention provide a structure and a method of forming an array of pillar-type memory devices where a second encapsulation material is deposited over a conventional encapsulation material and etched back. The second encapsulation material decreases the size of the space or gap-fill between adjacent pillars in the array of pillar-type memory devices that needs to be filled prior to top electrode contact formation. Embodiments of the present invention reduce the required gap-fill volume for the interlayer dielectric material by depositing the second encapsulation material over the first (i.e., conventional) encapsulation material on each of the pillar-type memory devices in an array of pillar-type memory devices.

After depositing the second encapsulation material, the gap to be filled by the interlayer dielectric has a v-shape with a more angled, sloped sidewall surface that makes filling the gap between adjacent pillars easier for the interlayer dielectric material. Embodiments of the present invention provide a level, void-free interlevel dielectric material surface which reduces the capture of top electrode contact metal during top electrode contact formation. Embodiments of the present invention include a method and a semiconductor structure that provides complete interlayer dielectric gap-fill and a level or flat interlayer dielectric material surface prior to contact formation that reduces electrical shorting between adjacent top electrode contacts in the array of pillar-type memory devices.

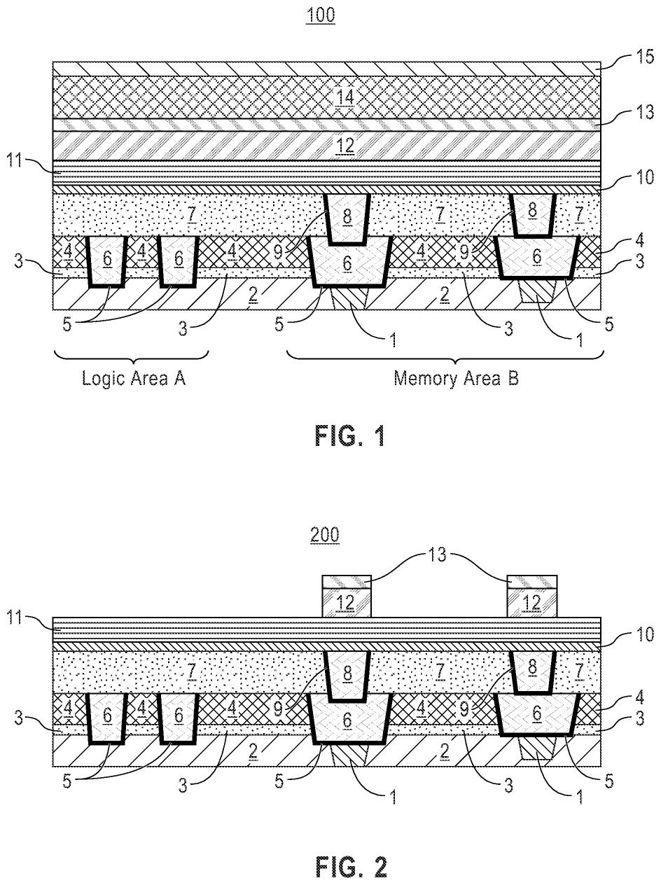

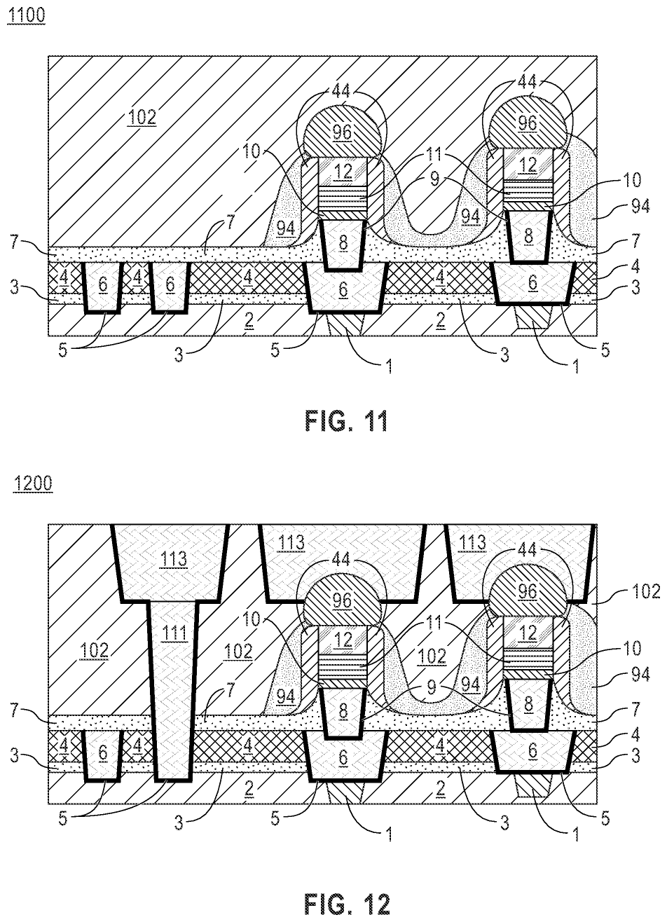

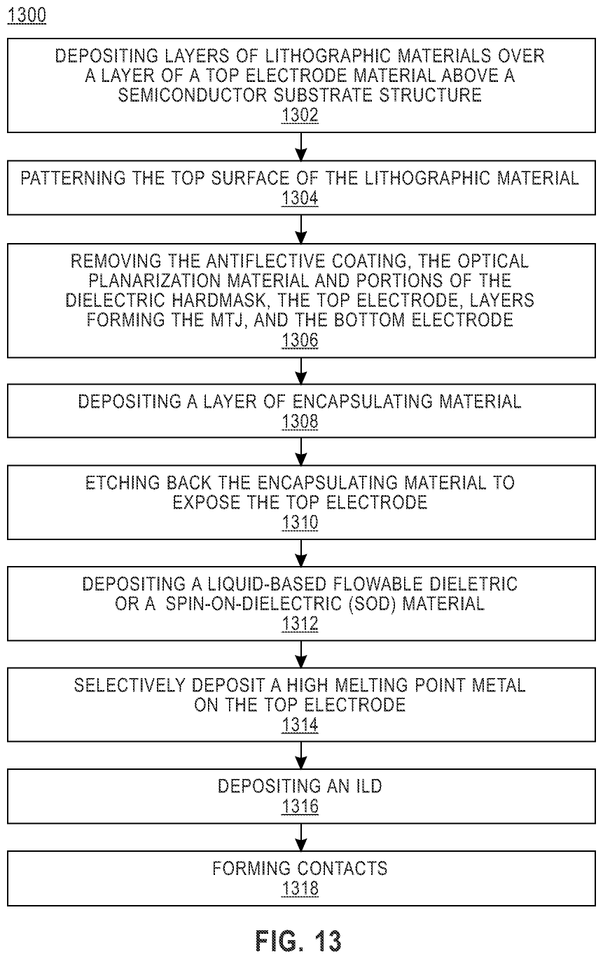

FIGS. 1-12 depict MRAM pillars with a magnetic tunnel junction (MTJ) in MTJ stack 11, bottom electrode (BE 10), and top electrode 12. In other embodiments, a different type of non-volatile memory technology, such as a phase change random-access memory (PCRAM) device or a resistive random-access memory (RRAM or ReRAM) device using a vertical or pillar structure with a bump formed on the top electrode may be formed. As known to one skilled in the art, using similar or the same processes as discussed with respect to FIGS. 1-12 a pillar-type PCRAM device or RRAM device can be formed with a metal bump or semi-spherical metal deposit on the top electrode of the device. For example, a metal bump such as electrode bump 66 is depicted in FIG. 8 or metal bump 96 depicted in FIG. 12 can be formed on a PCRAM device or an RRAM device using the process steps in FIG. 13 and as depicted in FIGS. 1-12 associated with metal bump formation on the pillar-type memory device top electrode.

Embodiments of the present invention also provide methods of forming an array of pillar-type memory devices with thinner top electrodes and a bump of a conductive metal selectively deposited on the thinner top electrode of each of the pillar-type memory devices in the array. The method includes depositing layers of material forming a plurality of pillars of a pillar-type memory device using conventional deposition processes, such as chemical vapor deposition (CVD), physical vapor deposition (PVD), or atomic layer deposition (ALD). The layers of materials, deposited with known deposition methods include one or more layers of lithographic materials over a layer of an electrode material for a top electrode that is deposited on several layers of one or more memory device materials, such as several layers of materials to form one or more magnetic tunnel junctions (MTJs), and a layer of another electrode material under the MTJs materials for a bottom electrode that is on a bottom contact. Embodiments of the present invention provide a layer of electrode material for a thinner patterned top electrode as compared to a layer of a conventional top electrode material for conventional patterned top electrode formed using an equivalent device technology.

The method includes using an ion beam etch process, which may be an angled ion beam etch process, to form the shorter memory device pillars due to the thinner layer of the top electrode material. The deposition of an encapsulation dielectric material over the semiconductor structure occurs using one of ALD, PVD, or CVD. The method includes using a reactive ion etch (RIE) to etchback the encapsulation dielectric material. After etching back the encapsulation dielectric material, the top surface of the top electrode is exposed along with a dielectric material that is between pillars in the array of pillars for the pillar-type memory devices.

Embodiments of the present invention provide a self-leveling dielectric material that can be a flowable, liquid-based dielectric that is deposited by one of a spin-on process or a vacuum CVD process. The self-leveling dielectric material covers a bottom portion of the encapsulation material extending approximately halfway up the encapsulation material. The self-leveling dielectric material, which may be a low-k dielectric material, fills a bottom portion of the gaps between adjacent memory device pillars. The deposition of the flowable, liquid-based dielectric material between the pillars in the array reduces the gap-fill volume for the ILD material during later top electrode contact formation processes.

Embodiments of the present invention provide a method of forming a pillar-type memory device that includes selectively depositing a conductive material such as a high melting point metal or a metal nitride on the thinner top electrode. The deposited conductive material forms a bump or a semi-spherical-like shaped element on the thinner top electrode. The bump of the conductive material acts as an extension to the thinner top electrode. The bump of conductive material effectively acts as a portion of the top electrode and effectively increases the height of the top electrode during top electrode contact formation.

Embodiments of the present invention provide the method of effectively forming a two part top electrode. A bottom portion or part of the top electrode is formed using conventional deposition and ion beam etch processes while the top portion of the top electrode is formed using a selective deposition process on the bottom portion of the top electrode. The selectively deposited conductive material essentially acts as a portion of the top electrode.

The method includes depositing an interlayer dielectric over the encapsulation material on the array of pillar-type memory devices, the bump of conductive material forming the extension or top portion of the top electrode, and over the dielectric material residing between the array of pillar-type memory devices. Using known BEOL processes, such as damascene processes, the top electrode contacts are formed in the deposited interlayer dielectric material.

Embodiments of the present invention also provide a second method of forming an array of pillar-type memory devices with a bump of selectively deposited conductive metal on a thinner top electrode and a second encapsulation material that is over the first, conventional encapsulation material. In the second method of forming the pillar-type memory devices in an array, each of the pillar-type memory devices is covered by a first and a second encapsulation material and a second encapsulation material.

The second method includes depositing the layers of the materials (i.e., the materials for forming the pillars for each of the pillar-based memory devices) using conventional deposition processes as discussed above. The deposition includes depositing a thinner top electrode (e.g., less than 100 nm) layer of the top electrode material. Using the ion beam etch (IBE) process removes portions of the layers of materials to form the shorter pillars for each of the pillar-type memory devices.

Embodiments of the present invention also provide the method that uses one of ALD, PVD, or CVD to deposit a first encapsulation material over the semiconductor structure. Using the RIE etchback process discussed above, the horizontal portions of the first encapsulation material are etched back exposing the top electrode.

Embodiments of the present invention provide the second method includes using ALD to selectively deposit the conductive material, such as a high melting point metal or a metal nitride material over the top electrode after the ion beam etch forms the pillars of the pill-like memory devices. The selectively deposited conductive material forms a semi-spherical-like bump of the conductive material on the top electrode that effectively increases the height of the top electrode on each of the pillar-type memory devices.

A second encapsulation material is deposited over the semiconductor structure. Using an RIE, the second dielectric material is etched back exposing a top portion of the bump of the conductive material on the top electrode and a portion of the dielectric material outside of the array of pillar-type memory devices. After the etching back process, portions of the second dielectric material remain over the first encapsulation material, a bottom portion of the bump of the conductive material, and above the dielectric material residing adjacent to and between the bottom contacts to the bottom electrode of each of the pillar-type memory devices. The second encapsulation material creates a v-like shape of the gap between the pillar-type memory devices and reduces the space or gaps between adjacent pillars in the array of pillars.

After depositing the second dielectric material that reduces the gaps between adjacent pillars and provides a steeper, V-shaped gap between adjacent pillars of the array of pillars in the semiconductor structure. The V-shaped gap between adjacent pillars with a steep slope improves the gap-fill of the interlayer dielectric between adjacent pillars in the next process step. A layer of an interlayer dielectric material is deposited over the semiconductor structure. The smaller gap between adjacent pillars with steeper sidewalls formed by the second encapsulation material improves the interlayer dielectric gap-fill and reduces ILD voids in the ILD surface and shorts between adjacent top electrode contacts formed in the ILD material. Using known BEOL processes, such as damascene processes, top electrode contacts are formed in a metal layer deposited over the bumps of conductive material on the top electrodes of each of the pillar-type memory devices.

Detailed embodiments of the claimed structures and methods are disclosed herein. The method steps described below do not form a complete process flow for manufacturing integrated circuits, such as semiconductor devices. The present embodiments can be practiced in conjunction with the integrated circuit fabrication techniques currently used in the art, for advanced semiconductor devices, such as advanced semiconductor devices using twenty-five nanometer or smaller design features, and only so much of the commonly practiced process steps are included as are necessary for an understanding of the described embodiments. The figures represent cross-section portions of a logic region and a memory region of a semiconductor device after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

Deposition processes as used herein include but are not limited to chemical vapor deposition (CVD), plasma vapor deposition (PVD), electroplating, ionized plasma vapor deposition (iPVD), atomic layer deposition (ALD), and plasma-enhanced chemical vapor deposition (PECVD). ALD processes are based on alternating exposures of a precursor and a coreactant (e.g., a reactant) that react with the surface of a target area in a self-terminating fashion. By repeating these alternating reactions in a cyclic manner, ALD results in the layer-by-layer deposition of a desired material on the substrate. Due to the surface-dependent nature of ALD chemistry, the differences in local surface properties can be exploited to deposit a film in an area-selective manner, in which deposition occurs on some regions of a patterned substrate and not others. In this way, and area-selective deposition such as an area-selective ALD can provides a selective, self-aligned, bottom-up fabrication technique.

As known to one skilled in the art, typical BEOL processes discussed herein include dual damascene, single damascene, and subtractive metal etching processes. Dual damascene processes are most commonly used for BEOL patterning and metallization processes. A dual damascene process typically includes patterning via and trench in a dielectric material, such as an interlayer dielectric, and filling the via holes and trenches with a deposited layer of metal (e.g., a BEOL metal including but not limited to copper, tungsten, cobalt, or ruthenium) and leveling the metal using a chemical mechanical (CMP) process to remove overburden or excess metal. The single damascene process includes patterning via holes in a first dielectric material, filling the via holes with a deposited metal layer, and then preforming a CMP to remove overburden or excess metal and then depositing a second dielectric material and then, performing a second etch process to form trenches, filling the trenches with metal layers and then performing a CMP to remove the overburden of metal layers. In some embodiments, a subtractive metallization process is used where a metal layer is deposited, patterned, etched, and a dielectric material is deposited over the top surface. A CMP exposes the top surface of the patterned metal.

Patterning processes discussed herein include but are not limited to one of lithography, photolithography, an extreme ultraviolet (EUV) lithography process, or any other known semiconductor patterning process that is followed by one or more of the following etching processes discussed below.

Etching processes discussed herein to remove portions of material as patterned or masked by the lithography process includes etching processes, such as dry etching process using a reactive ion etch (RIE), or ion beam etch (IBE), a wet chemical etch process, or a combination of these etching processes and is not limited to these etching processes.

References in the specification to “one embodiment”, “other embodiment”, “another embodiment,” “an embodiment,” etc., indicate that the embodiment described may include a particular feature, structure, or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top”, “bottom,” and derivatives thereof shall relate to the disclosed structures and methods, as oriented in the drawing figures. The terms “overlying,” “atop,” “over,” “on “positioned on,” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

In the interest of not obscuring the presentation of the embodiments of the present invention, in the following detailed description, some of the processing steps, materials, or operations that are known in the art may have been combined for presentation and illustration purposes and in some instances may not have been described in detail. Additionally, for brevity and maintaining a focus on distinctive features of elements of the present invention, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present

FIG. 1 is a cross-sectional view of semiconductor structure 100 after depositing one or more layers of lithographic material over a layer of electrode material for a magnetoresistive random access memory (MRAM) device in accordance with an embodiment of the present invention. As depicted, FIG. 1 includes dielectric layer 2 as an interlayer dielectric (ILD), interconnects 1, cap 3, ILD 4, Mx metal 6, liner 5, dielectric material 7, bottom contact 8, contact liner 9, bottom electrode (BE) 10, the layers of materials for magnetic tunneling junction in MTJ stack 11, top electrode 12, dielectric hardmask 13, organic planarization layer (OPL) 14, and lithographic hardmask 15. Also, depicted in FIG. 1 is logic area A and memory area B. Logic area A is a portion of semiconductor structure 100 above one or more logic devices in or above the semiconductor substrate (not depicted in FIG. 1), and memory area B is the portion of semiconductor structure 100 on the semiconductor substrate (not depicted) that will include one or more arrays of pillar-type memory devices (e.g., MRAMs, phase change memory devices, resistive random-access memory devices).

Interconnects 1 can be a number of interconnections to semiconductor devices below semiconductor structure 100, such as complementary metal-oxide semiconductor (CMOS) devices. Interconnects 1 can be any conductive material, metal, or metal compound (e.g., copper, cobalt, etc.) used in interconnections from semiconductor devices (e.g., formed in the front end of the line semiconductor processes) and the metal layers above the semiconductor devices. In some embodiments, a liner material surrounds the sidewalls and bottom surface of interconnects 1. Interconnects 1 may contact liner 5 surrounding Mx metal 6 in memory area B, where the rightmost two portions of Mx metal 6 that are in memory area B can be bottom electrode contacts. In some embodiments, interconnects 1 reside under one or more of Mx metal 6 in logic area A, where the two leftmost portions of Mx metal 6 in logic area A can be a line or a contact.

Dielectric layer 2 can be an ILD. Dielectric layer can be a dielectric material such as a silicon-based oxide surrounding interconnects 1, a bottom portion of liner 5, and under cap 3. For example, dielectric layer 2 may be composed of one of silicon nitride (SiN), a silicon oxide (SiOx), a silicon carbide nitride (SiCN or SiCN(H)), a low-k or ultra-low-k dielectric material where x in SiOx denotes a number of oxygen atoms present in the compound (e.g., SiO₂). A low-k dielectric material has a dielectric constant that is less than 3.9 and an ultra-low-k dielectric material has a dielectric constant that is less 2.5. Dielectric layer 2 is not limited to the dielectric materials included above but can be any suitable dielectric material used in semiconductor device fabrication.

In various embodiments, cap 3 is a layer of a dielectric material. Cap 3 resides over dielectric layer 2 and between portions of liner 5 on Mx metal 6. In various embodiments, cap 3 is composed of SiN, SiC, SiCN(H), SiCNO, or another suitable dielectric material used in a cap dielectric layer.

In various embodiments, ILD 4 resides above cap 3 and surrounds a top portion of liner 5 that surrounds each of Mx metal 6. ILD 4 can be composed of an ultra-low-k dielectric material, such as but not limited to a carbon-containing silicon oxide (e.g., SiOC) or another ultra-low-k material used in memory device formation. Ultra-low-k dielectric materials may have a dielectric constant less than or equal to 3. As depicted, ILD 4 is under a layer of dielectric material 7.

One or more portions of Mx metal 6 reside in ILD 4 and are surrounded by liner 5 on the sidewalls and bottom surface of each of Mx metal 6. Liner 5 can be any liner material used for covering portions of metal contacts and may be composed of TaN, Ta, Ti, etc., but liner 5 is not limited to these liner materials. In various embodiments, each of Mx metal 6 is a portion of a middle of line metal (MOL) layer or a portion of a back end of the line (BEOL) metal layer (e.g., a portion of M2 metal layer, M1 metal layer, M3 metal layer, etc.). As depicted, Mx metal 6 can be portions of the Mx metal layer in logic area A or in memory area B. Bottom contacts 8 with sidewalls and bottom surfaces covered by contact liner 9 may reside above and contact each of Mx metal 6 in the memory area B. Mx metal 6 may be formed using known BEOL metallization processes.

In various embodiments, dielectric material 7 resides under bottom electrode 10, above ILD 4, portions of Mx metal 6 in logic region A, portions of Mx metal 6 in memory region B, and surrounds bottom contacts 8 that can be covered with contact liner 9. Dielectric material 7 can be composed of SiN, SiC, SiCN(H), SiCNO, or another suitable dielectric material used to electrically isolate contacts. In some embodiments, dielectric material 7 is the same material as cap 3. In some cases, dielectric material 7 is a different material than cap 3.

As depicted in FIG. 1, bottom contacts 8 reside in dielectric material 7 on Mx metal 6 and under a layer of electrode material (e.g., BE 10). Bottom contacts 8 can be composed of any BEOL metal material, such as copper (Cu), tungsten (W), cobalt (Co), ruthenium (Ru), aluminum (Al) but is not limited to these BEOL materials. Contact liner 9 can surround the sidewalls and bottom surface of bottom contact 8. Contact liner 9 can be any liner material used in contact formation. As depicted, bottom contact 8 are in memory area B and any number of bottom contacts 8 may be present in semiconductor structure 100. In various embodiments, a pitch or space between each of bottom contacts 8 that is less than 200 nm. Bottom contact 8 with contact liner 9 can be formed using known patterning and etching of dielectric material 7 that is followed by contact metal deposition (e.g., by CVD, PVD, electroplating, etc.) and a chemical mechanical polish (CMP).

In various embodiments, a layer of electrode material for BE 10 resides above dielectric material 7 and the top surfaces of bottom contact 8 and contact liner 9. BE 10 can be composed of any electrode material used in memory devices, such as MRAM devices. For example, BE 10 may be composed of but is not limited to, niobium (Nb), W, WN, tantalum (Ta), TaN, titanium (Ti), TiN, Ru, molybdenum (Mo), chromium (Cr), vanadium (V), aluminum (Al) or another high melting point metal or conductive metal nitride materials. BE 10 resides under the layers of material for forming a magnetic tunneling junction for MTJ stack 11. BE 10 may be deposited by CVD, PVD, ALD, or another suitable deposition method.

The layers for one or more magnetic tunneling junctions (MTJ) in an MTJ stack 11 reside above BE 10 and under the layer of electrode material for top electrode 12. MTJ stack 11 may be composed of a large number of layers of magnetic and non-magnetic materials used in forming one or more magnetic tunneling junctions in a MRAM device. For example, some of the typical materials in an MRAM stack can include a tunneling layer composed of magnesium oxide, a hardmask such as TaN, a freelayer (e.g., CoFeB), a plurality of layers of different materials in a reference layer, and a metal layer which can be a metal seed layer composed of Ru, Ta, NiCr, or a combination of these materials, however, MTJ stack 11 is not limited to these materials. In some embodiments, the layers of materials labelled in MTJ stack 11 are layers of materials such as phase change materials or resistive materials used in pillar-type phase-change memory devices or pillar-type RRAM devices rather than layers of materials for MTJ stack 11. The various layers of MTJ stack 11 may be deposited by ALD, or another suitable deposition process. In some embodiments, the top hardmask layer in MTJ STACK 11MTJ stack 11 is thinner to reduce MTJ stack height. While FIG. 1 specifically identifies an MTJ as a portion of the pillar depicted in a MRAM device stack, in other embodiments, the layers of materials forming the pillar include one of one or more layers of a phase change material to form a pillar-type PCRAM device or one or more layers of a thin oxide layer (e.g., HfO₂) capable of forming oxygen vacancies that can charge and drift under an electric field to form a pillar-type RRAM device.

A second layer of an electrode material for top electrode 12 is deposited over MTJ STACK 11. Top electrode 12 can be composed of any of the electrode materials previously discussed with respect to BE 10. For example, top electrode 12 may be W, Ta, TaN, Ti, another high melting point metal, or a conductive metal nitride material. Top electrode 12 may be deposited by one of CVD, PVD, ALD, or another suitable deposition process. The thickness of top electrode 12 is less than 100 nm. The thickness of top electrode 12 is less than the thickness of a top electrode in a conventional MRAM device which typically have top electrodes with a thickness of greater than 100 nm. As previously discussed, the thinner top electrode material layer for top electrode 12 reduces shadowing during pillar etch in later process steps (e.g., reduces the risk of device shorting due to MTJ material residue between pillars with tall top electrodes) and improves MRAM device yields as MRAM device pitch decreases.

In various embodiments, a number of layers of different materials for lithography and patterning of top electrode 12 and the other layers form the MRAM pillar for the MRAM device. As depicted, a layer of dielectric hardmask 13 which can be of SiN, SiOx, or another suitable dielectric hardmask material resides on top electrode 12. Dielectric hardmask 13 may be covered by an organic planarization layer (OPL) and a layer of a low-temperature oxide or SiON, and an anti-reflective coating (ARC/BARC) used for lithographic hardmask 15.

FIG. 2 is a cross-sectional view of semiconductor structure 200 after patterning and etching portions of the lithographic materials and the electrode material in accordance with an embodiment of the present invention. As depicted, FIG. 2 includes the elements of FIG. 1 without OPL 14, lithographic hardmask 15, and portions of dielectric hardmask 13 and top electrode 12. The top surface of lithographic hardmask 15 is patterned. Using one or more known etching processes, portions of top electrode 12 under dielectric hardmask 13 remain after removing lithographic hardmask 15, OPL 14, portions of dielectric hardmask 13, and portions of top electrode 12. After the patterning and etching of the lithographic materials, for example, using a reactive ion etch (RIE), portions of top electrode 12 and dielectric hardmask 13 remain on MTJ STACK 11 and the remaining top surface of MTJ STACK 11 is exposed as depicted in FIG. 2.

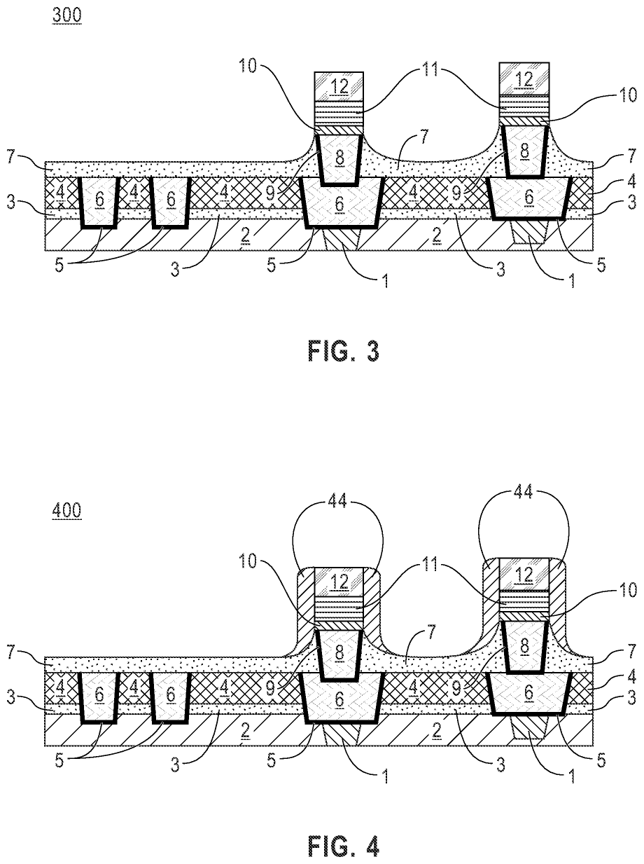

FIG. 3 is a cross-sectional view of semiconductor structure 300 after etching the MTJ stack 11, the BE 10, and removing a layer of hardmask over the MTJ stack 11 in accordance with an embodiment of the present invention. In various embodiments, using ion beam etching, the MRAM pillar may be formed. An ion beam etch (IBE) process removes portions of MTJ STACK 11MTJ stack 11, BE 10, and dielectric material 7 not under dielectric hardmask 13 depicted in FIG. 2. Ion beam etching is a physical etching technique where ions (e.g., argon ions) are accelerated towards the sample in a vacuum chamber. The layer of dielectric hardmask 13 is removed during the IBE, which may be an angled IBE that removes the top portion of dielectric material 7 leaving a curved top surface of dielectric material 7 adjacent to BE 10 as depicted in FIG. 3. In some embodiments, the angled IBE removes dielectric hardmask 13 from the top surface of top electrode 12.

FIG. 4 is a cross-sectional view of semiconductor structure 400 after depositing encapsulation 44 and etching back a portion of encapsulation 44 in accordance with an embodiment of the present invention. As depicted, FIG. 4 includes encapsulation 44, top electrode 12, MTJ stack 11, BE 10, bottom contact 8 with contact liner 9, dielectric material 7, Mx metal 6 with liner 5, ILD 4, cap 3, dielectric layer 2, and interconnects 1 in dielectric layer 2. Logic area A and memory area B are not labeled in FIG. 4 but are present as identified in FIG. 1.

A layer of dielectric material for encapsulation 44, such as SiN, SiC, SiCN(H), or any other encapsulating dielectric material used for over MRAM pillars or stacks can be deposited by ALD, PVD, or CVD, for example, over dielectric material 7, MTJ stack 11, and top electrode 12. Using an RIE, for example, an etch-back of encapsulation 44 removes portions of encapsulation 44 from the horizontal surfaces of semiconductor structure 400. The RIE etch-back exposes the horizontal top surface of top electrode 12 and portions of the top surface of dielectric material 7 that are not adjacent to BE 10. Some of the portions of encapsulation 44 adjacent to the MRAM pillars composed of BE 10, MTJ stack 11, and top electrode 12 remain on the curved surfaces of dielectric material 7 as depicted in FIG. 4.

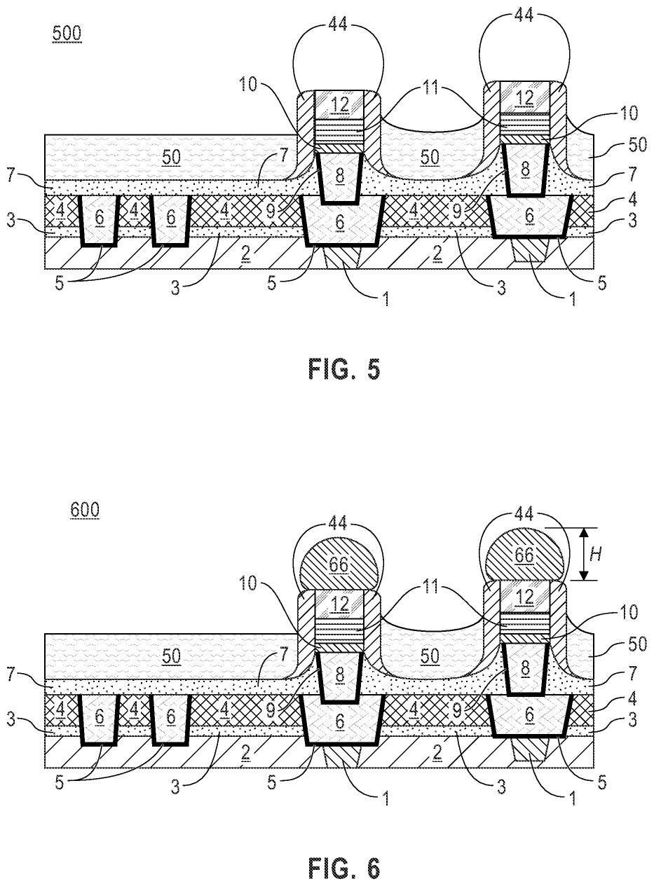

FIG. 5 is a cross-sectional view of semiconductor structure 500 after depositing a self-leveling dielectric 50 around the MRAM pillars and over dielectric material 7 in accordance with an embodiment of the present invention. As depicted, FIG. 5 includes the elements of FIG. 4 and self-leveling dielectric 50. As depicted, self-leveling dielectric 50 is above exposed surfaces of dielectric material 7 and surrounding a bottom portion of encapsulation 44. As depicted, self-leveling dielectric 50 covers a bottom portion of encapsulation 44. For example, self-leveling dielectric 50 extends up encapsulation 44 to a level ranging from approximately the same as the height of the bottom portion of MTJ stack 11 to the height of the bottom of top electrode 12. The height of self-leveling dielectric 50 on semiconductor structure 500 may be different in other examples. In various embodiments, self-leveling dielectric 50 is a spin-on-dielectric (SOD) material or a flowable, low-k dielectric material, such as an flowable SiOCH (silicon, oxygen, carbide, hydrogen) material but is not limited to these materials. Self-leveling dielectric 50 may be deposited using a vacuum plasma chemical vapor deposition process or a spin-on process. In various embodiments, the top surface of top electrode 12 is cleaned using one of a dry etch process (e.g., an RIE) or a wet chemical etch as top electrode 12 surface cleaning processes. After the cleaning process, the top surface of top electrode 12 is exposed and free of residual dielectric material.

FIG. 6 is a cross-sectional view of semiconductor structure 600 after selectively depositing electrode bump 66 over top electrode 12 in accordance with an embodiment of the present invention. As depicted, FIG. 6 includes the elements of FIG. 5 and electrode bump 66 with a height, labeled H. A portion of the conductive material is added to the top electrode 12 forming electrode bump 66. For example, by the selective d Electrode bump 66 can be selectively deposited over top electrode 12 to form electrode bump 66. A selective deposition of electrode bump 66 on top electrode 12 occurs, for example, by an area-selective ALD process. The selective deposition of electrode bump 66 on top electrode 12 deposits or grows electrode bump 66 to a height, depicted as H in FIG. 6. In some examples, a small portion of electrode bump 66 may extend over a small portion of the top surface of encapsulation 44 adjacent to top electrode 12. In other words, a lower portion of the selectively deposited electrode bump 66 is slightly wider than top electrode 12. Electrode bump 66 may be composed of any electrode material, such as niobium (Nb), W, WN, tantalum (Ta), TaN, titanium (Ti), TiN, Ru, molybdenum (Mo), chromium (Cr), vanadium (V), aluminum (Al) and other high melting point metals or conductive metal nitride materials but is not limited to these electrode materials.

As previously discussed, by depositing electrode bump 66 on top electrode 12, the thinner layer of top electrode 12 deposited as discussed with respect to FIG. 1 provides a lower height for top electrode 12 during the IBE etch of some of the MRAM pillar materials (e.g., MTJ stack 11, BE 10, and the top portion of dielectric material 7). The lower MRAM pillar with the lower top surface of top electrode 12 reduces shadowing during IBE and reduces the probability of inefficient MRAM pillar sidewall clean-up after IBE etch. When residual portions of MRAM materials remain on the MRAM pillar sidewall after cleaning, shorting of the MRAM device may occur. An ability to form electrode bump 66 on top electrode 12 improves the ability of the IBE process to remove the portions of the MRAM pillar and MRAM stack 11 due to less shadowing created by adjacent MRAM pillars in an array of MRAM stacks 11. The ability to provide both a lower MRAM pillar during IBE and an increased top electrode height with electrode bump 66 both reduces electrical shorts created during IBE and allows embedding MRAM pillars when intermetal spacing between Mx and Mx+1 is large. Using electrode bump 66 and self-leveling dielectric 50 reduces the aspect ratio for ILD fill between MRAM pillars. This prevents ILD void formation eliminating electrical shorts between top contacts formed in the Mx+1 metal layer above top electrode 12.

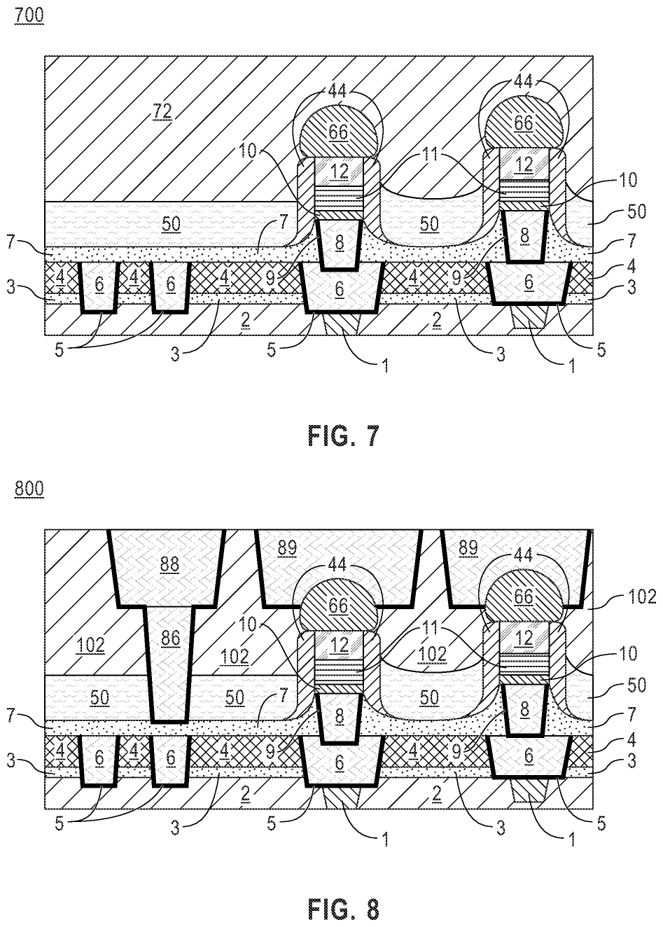

FIG. 7 is a cross-sectional view of semiconductor structure 700 after depositing ILD 72 over exposed surfaces of self-leveling dielectric 50, encapsulation 44, and electrode bump 66 in accordance with an embodiment of the present invention. As depicted, FIG. 7 includes the elements of FIG. 6 with ILD 72. ILD 72 can be deposited by PVD, CVD, ALD, etc. over exposed surfaces of self-leveling dielectric 50, encapsulation 44, and top electrode 12. A CMP may be performed after the deposition of ILD 72. ILD 72 may be composed of SiN, SiOx, SiCN, SiCN(H), a low-k dielectric material, or an ultra-low-k dielectric material.

FIG. 8 is a cross-sectional view of semiconductor structure 800 after forming via 86, contacts 88, and top electrode contact 89 in ILD 72 in accordance with an embodiment of the present invention. As depicted, FIG. 8 includes the elements of FIG. 7 with via 86 and contact 88 formed in logic area A and top electrode contact 89. Via 86, contact 88, and top electrode contact 89 electrically connect Mx metal 6 to an Mx+1 metal layer that is deposited over ILD 72 after patterning and etching ILD 72 in a damascene metallization process. Using previously discussed damascene processes for via 86, contact 88 and 89 formation in ILD 72, via 86 connects one of the portions of Mx metal 6 to contact 88 in logic area A. As depicted, contact 89 connecting two electrode bumps 66 is formed in memory area B using the Mx+1 metal layer. While FIG. 8 depicts only two MRAM stacks 11 and two electrode bumps 66, in other embodiments, an array of many MRAM stacks 11 each MTJ stack 11 with top electrode 12, electrode bump 66, BE 10, and Mx metal 6. As depicted in FIG. 8, encapsulation 44 does not cover electrode bump 66. Additionally, as depicted, a bottom portion of electrode bump 66 can be wider than top electrode 12. In some embodiments, contacts 89 are bitlines connecting to metal bump 96 and top electrode 12.

As depicted in FIG. 8, electrode bump 66 and top electrode 12 create a tall electrode structure that provides sufficient height or space between the MTJ in MTJ stack 11 and top electrode contact 89 to prevent shorting of top electrode contact 89 with MTJ stack 11. Self-leveling dielectric 50 reduces the height of the ILD fill (e.g., using ILD 72) to prevent ILD voids during ILD 72 deposition. The ILD voids can capture BEOL metal from the Mx+1 metal layer during top contact formation and cause electrical shorting between adjacent Mx+1 lines in memory area B.

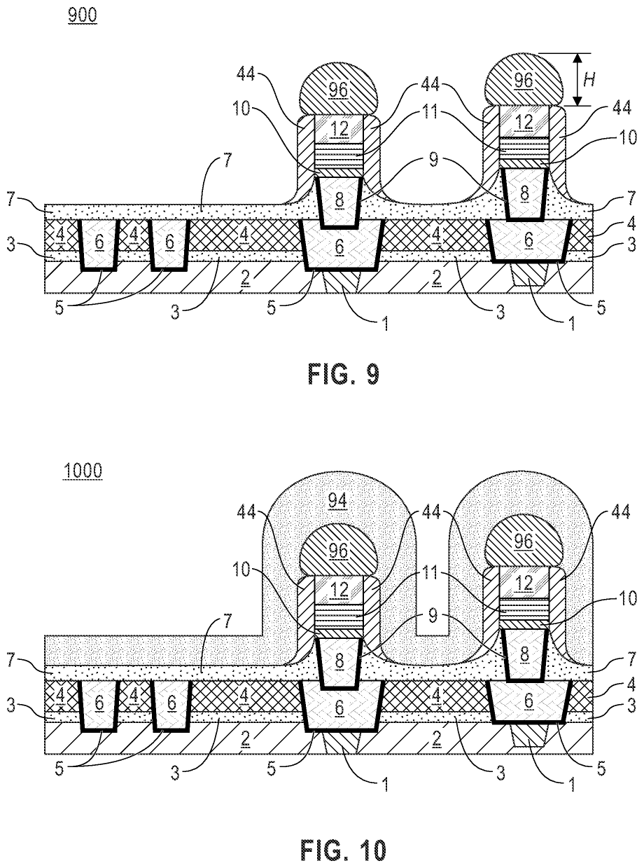

FIG. 9 is a cross-sectional view of semiconductor structure 900 after selectively depositing an additional metal material for electrode bump 66 over top electrode 12 of the MRAM pillar depicted in FIG. 4 in accordance with a second embodiment of the present invention. As depicted, FIG. 9 includes the elements of FIG. 4 and metal bump 96. Using the materials and processes previously discussed in detail with respect to FIG. 4 and FIG. 6, electrode metal bump 96 can be deposited over top electrode 12. Metal bump 96 is essentially the same or similar to electrode bump 66 depicted in FIG. 6 (e.g., can be one of the same conducive materials with deposited with same deposition or similar process). Metal bump 96 can be selectively deposited with the same or similar processes as used for the deposition of electrode bump 66. For example, using an area selective ALD process enables depositing metal bump 96 only on top electrode 12. As depicted, a bottom portion of selectively deposited metal bump 96 can be slightly wider than top electrode 12. As depicted, metal bump 96 is deposited with a height H, where the height H of metal bump 96 is essentially the same or similar to the height H of electrode bump 66 in FIG. 6. The height H added to top electrode 12 by metal bump 96 effectively provides a taller top electrode without increased top electrode height during IBE etch and MRAM pillar formation. As previously discussed, the MRAM pillar formation for the MRAM device includes the IBE etch of BE 10, MTJ stack 11, and top electrode 12 where the higher top electrode 12 is, the harder it is to keep the sidewalls of the formed MRAM pillars clean after IBE. In some examples, a small portion of metal bump 96 may extend over a small portion of encapsulation 44.

FIG. 10 is a cross-sectional view of semiconductor structure 1000 after depositing a dielectric material as a second encapsulating material over encapsulation 44 in accordance with the second embodiment of the present invention. As depicted, FIG. 10 includes the elements of FIG. 9 and encapsulation 94. A layer of dielectric material for a second encapsulation material can be deposited by ALD, PVD, or CVD, for example, over dielectric material 7, encapsulation 44, and metal bump 96 to form encapsulation 94. Encapsulation 94 may be composed of a different encapsulation material than encapsulation 44 or the same dielectric material as encapsulation 44. For example, encapsulation 94 can be composed of SiN, SiC, SiCN(H), or any other encapsulating dielectric material used for over MRAM pillars in MRAM devices.

FIG. 11 is a cross-sectional view of semiconductor structure 1100 after etching back encapsulation 94 and depositing ILD 102 in accordance with the second embodiment of the present invention. An etchback of encapsulation 94 can occur using an RIE to remove portions of encapsulation 94 from the horizontal surfaces of dielectric material 7 and metal bump 96. The RIE etch-back exposes the horizontal top surface of metal bump 96 and portions of the top surface of dielectric material 7 that is horizontal and not adjacent to BE 10. After the etchback of encapsulation 94, encapsulation 94 provides a more angled sidewall surface than encapsulation 44 alone does. In some cases, an optional dry or wet cleaning process may occur after etchback to ensure a clean top surface of metal bump 96. After etching back encapsulation 94, a portion of encapsulation 94 remains on the bottom portion of metal bump 96.

After depositing and etching back encapsulation 94, there is less area for ILD fill in the next process step is needed as compared to the ILD fill required for semiconductor structure 600 that only has encapsulation 44 on the MRAM pillars. Also, the taper profile of encapsulation 94 after etchback helps with void-free ILD fill between MRAM pillars.

FIG. 12 is a cross-sectional view of semiconductor structure 1200 after depositing an Mx+1 metal layer and forming via 111 and contacts 112 and 113 in accordance with the second embodiment of the present invention. As depicted, FIG. 12 includes via 111 and contact 112 in logic area A, contacts 113 in memory area B, metal bump 96 connecting to contacts 113, top electrode 12 under metal bump 96, MTJ stack 11, BE 10, bottom contact 8, contact liner 9, Mx metal 6, liner 5, ILD 4, cap 3, dielectric layer 2, and interconnects 1. As depicted, contacts 113 in memory area B are top electrode contacts connecting to metal bump 96 on top electrode 12 of the pillar-type memory device (e.g., BE 10 on bottom contact 8, MTJ stack 11, top electrode 12 with metal bump 96 form the memory device). As depicted in FIG. 12, encapsulation 44 and encapsulation 94 do not cover metal bump 96. In some embodiments, contacts 113 are bit lines connecting to metal bump 96 and top electrode 12.

FIG. 13 is an example of a method 1300 of forming an array of embedded pillar-type memory devices with a thinner top electrode and an additional electrode metal selectively deposited on the thinner top electrode in accordance with an embodiment of the present invention.

In step 1302, the method includes depositing layers of lithographic materials over a layer of top electrode material. The lithographic layers can include one or more of known materials used in lithographic patterning for forming memory device pillars. For example, the lithographic layers may include an anti-reflective coating (ARC or BARC), an organic planarization layer, and a dielectric hardmask material (e.g., SiN, TEOS, etc.) but is not limited to these materials.

The top electrode material is above a number of layers of materials for forming one or more MTJs on a bottom electrode above a semiconductor substrate. The layer of the top electrode material is thinner than the layer of top electrode material in conventional MRAM pillars (e.g., the top electrode material is less than 100 nm thick).

The bottom electrodes are above a bottom electrode contact in a dielectric material. The bottom electrode contacts are connected to an Mx metal layer in either a BEOL or a MOL semiconductor structure.

In step 1304, the method includes patterning the top surface of the lithographic materials on the semiconductor structure. Using known photolithography patterning processes, portions of the lithographic materials are exposed, and various layers or portions of the lithographic materials and the top electrode are removed.

In step 1306, the method includes removing portions of the MRAM pillar material layers and portions of the dielectric material that are not adjacent to the bottom electrode contacts. Exposed portions of layers of the MTJ and the bottom electrode material are removed under the top electrode using the remaining dielectric hardmask to protect the top electrode. During the etching process, the dielectric hardmask over the top electrode is removed.

The portions of the MTJ materials and the portions of the bottom electrode are removed using an IBE to form the MRAM pillar with the remaining top electrode material. The thinner top electrode material used in the embodiments of the present invention provides a lower semiconductor structure for the MRAM pillar formed using the IBE which can be an angled IBE process. As previously discussed, using the thinner top electrode reduces shadowing during IBE and improves MRAM device yield.

In step 1308, the method includes depositing a layer of an encapsulating material over the semiconductor structure. Using one of an ALD, PVD, or CVD process, a layer of dielectric encapsulation material is deposited over the exposed surfaces of the dielectric material and the MRAM pillars composed of the top electrodes, the MTJs, and the bottom electrodes with the bottom electrode contact. The dielectric materials for the encapsulating material include SiN, SiC, SiCN(H), or any other memory device encapsulating material.

In step 1310, the method includes etching back the encapsulating material to expose the top electrode. Using an RIE process, the encapsulating material is removed from the horizontal surfaces of the semiconductors structure. The encapsulating material is removed over the horizontal surfaces of the remaining dielectric material and from the top surface of the top electrode. Portions of the encapsulating material remain on the vertical sides of the top electrode, the MRAM stack forming the MTJ, the bottom electrode, and curved portions of the remaining dielectric material on the bottom contact (e.g., the encapsulating material remains on the sidewalls of the MRAM pillar).

In step 1312, depositing a liquid-based, flowable dielectric material or a spin-on-dielectric (SOD) material as a self-leveling dielectric material on the semiconductor structure. Using one of a spin-on process or a vacuum chemical vapor deposition process, a dielectric material is applied over the exposed surfaces of the dielectric material and the encapsulating material. The flowable dielectric material applied by CVD (fCVD) or the spin-on-dielectric material fills the gaps between encapsulating material on the MRAM pillars in the memory area (e.g., around the memory device pillars in an array of pillar-type memory devices) and with a level surface above the dielectric material above the logic devices in the semiconductor structure. The flowable dielectric material applied by CVD or by the spin coating process creates a relatively level surface in the memory device area and over the logic device. The dielectric material applied with spin-on processes also provides a relatively level top surface of the dielectric material. The dielectric material can be one of a low-k dielectric, an ultra-low-k dielectric material or a flowable SiOCH (silicon, oxygen, carbide, hydrogen) material. The ultra-low-k material can be but is not limited to SiOC and generally has a higher carbon-content than a low-k dielectric material. The higher carbon-content can reduce the dielectric constant of the dielectric material. The top surface of the SOD or fCVD material can be around the bottom portion of the top electrode to near the bottom portion of the MTJ in the MRAM pillar but the height of the top surface of the SOD or fCVD but is not limited these heights.

In step 1314, the method includes selectively depositing a high melting point metal on the top electrode. For example, using and area-selective ALD process or other selective ALD deposition process, a portion of a high melting point metal can form a bump or a semi-spherical-like shape on the top electrode. The conductive material or metal deposited can be one of Nb, NbN, W, WN, Ta, TaN, Ti, TiN, Ru, Mo, Cr, V, Pd, Pt, Rh, Sc, Al, a conductive metal nitride, or another high melting point metal. The deposited material forms a bump on the top electrode that effectively increases the height of the top electrode. Using the bump of deposited conductive material or metal can increase the effective height of the top electrode.

In step 1316, the method includes depositing an ILD over the semiconductor structure. Using known ILD materials such as SiN, SiOx, SiCN, SiCN(H), an ultra-low-k dielectric material that is deposited by a deposition process, such as CVD, PVD, or ALD, the ILD material is deposited on exposed surfaces of the flowable dielectric material or SOD, the encapsulating material, and the bump of conductive or metal material on the top electrode. The ILD is deposited with a thickness sufficient to allow the contacts in the Mx+1 metal to be formed above the bump of conductive material or metal on the top electrode. The SOD or the fCVD material provides a void-free fill and reduces the aspect ratio of the gap to be filled by this second ILD deposition.

In step 1318, the method includes forming contacts. Using known BEOL processes, trenches and via holes can be etched and the Mx+1 metal layer deposited to form vias and contacts above the logic device region and top electrode contacts connecting to the bump of conductive material or metal on each top electrode of the pillar-type memory devices in the memory region or area of the semiconductor structure. A CMP removes the BEOL metal from the top surface of the ILD and finishes the contact formation. As previously discussed, because the ILD is void-free before the Mx+1 metal deposition minimal to no BEOL metal is captured in voids in the ILD to cause shorting between adjacent contacts.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The methods described herein can be used in the fabrication of integrated circuit chips or semiconductor chips. The resulting semiconductor chips can be distributed by the fabricator in raw wafer form (that is, as a single wafer that has multiple unpackaged chips), as a bare die, or in a packaged form. In the latter case, the semiconductor chip is mounted in a single chip package (such as a plastic carrier, with leads that are affixed to a motherboard or other higher-level carrier) or in a multichip package (such as a ceramic carrier that has either or both of surface interconnections, or buried interconnections). In any case, the semiconductor chip is then integrated with other semiconductor chips, discrete circuit elements, and/or other signal processing devices as part of either (a) an intermediate product, such as a motherboard, or (b) an end product. The end product can be any product that includes semiconductor chips, ranging from toys and other low-end applications to advanced computer products having a display, memory, a keyboard or other input device, and a central processor.

What is claimed is:

1. A semiconductor structure of a pillar-type memory device, the semiconductor structure comprising:
a bump of a conductive material on a top electrode of a pillar-type memory device, wherein the bump of the conductive material increases a height of the top electrode.

2. The semiconductor structure of claim 1, wherein the top electric is a thin top.

3. The semiconductor structure of claim 1, wherein the bump of the conductive material is wider than the top electrode of the pillar-type memory device.

4. The semiconductor structure of claim 1, wherein the pillar-type memory device further comprises:
a bottom electrode contact on a metal layer in one of a back end of line metal layer or a middle of line metal layer;
a bottom electrode on the bottom electrode contact;
one or more magnetic tunnel junctions above the bottom electrode;
the top electrode on the one or more magnetic tunnel junctions;
the bump of conductive material on the top electrode; and
a first encapsulation material over sidewalls of the top electrode, the one or more magnetic tunnel junctions, the bottom electrode, and a dielectric material surrounding the bottom electrode contact on a portion of one of a back end of line metal layer of middle of line metal layer.

5. The semiconductor structure of claim 4, further comprising a second encapsulation material over the first encapsulation material and over a bottom portion of the bump of the conductive material.

6. The semiconductor structure of claim 4, wherein a bottom portion of the first encapsulation material is surrounded by a self-leveling dielectric material.

7. The semiconductor structure of claim 5, wherein the second encapsulation material is surrounded by an interlayer dielectric material.

8. An array of pillar-type memory devices, the array of pillar-type memory devices comprising:
a plurality of pillar-type memory devices in an array, wherein each of the pillar-type memory devices has a semi-spherical-like bump of a conductive material on a top electrode of each of the pillar type-memory devices in the array;
an encapsulation dielectric material covers a sidewall of each of the plurality of memory devices in the array and is not over the semi-spherical bump the conductive material;
a self-leveling dielectric material between bottom portions of the encapsulation material; and
an interlayer dielectric material is over the self-leveling dielectric material and between the semi-spherical-like bump of the conductive material on the top electrode of the pillar type-memory devices.

9. The array of pillar-type memory devices of claim 8, further comprising:
a plurality of bottom contacts in a dielectric material for each pillar-type memory device of the array of pillar-type memory devices, wherein each of the plurality of bottom contacts reside on a portion of a first metal layer; and
each of the semi-spherical-like bump of a conductive material on the top electrode of the pillar type-memory devices in the array of pillar-type memory devices contacts a top electrode contact formed in a second metal layer above the first metal layer.

10. The array of pillar-type memory devices of claim 9, wherein the first metal layer is in of one of a back end of line metal layer or a middle of line metal layer.

11. The array of pillar-type memory devices of claim 8, wherein the plurality of pillar-type memory devices in the array are one of a magnetoresistive random-access memory device, a resistive random-access memory, or a phase change random-access memory device.

12. The array of pillar-type memory devices of claim 8, wherein the semi-spherical-like bump of a conductive material on the top electrode of each of the pillar type-memory devices in the array is wider than the top electrode.

13. An array of pillar-type memory devices, the array of pillar-type memory devices comprising:
a plurality of pillar-type memory devices in an array, wherein each of the pillar-type memory devices in an array of pillar-type memory devices has a bump of a conductive material on a top electrode of each of the pillar type-memory devices in the array of pillar-type memory devices;
a first encapsulation dielectric material covers a sidewall each of the plurality of memory devices in the array of pillar-type memory devices;
a second encapsulation material is over the first encapsulation material and a bottom portion of the bump of the conductive material; and
an interlayer dielectric material over the second encapsulation material and between the bump of a conductive material on a top electrode of the pillar type-memory devices.

14. The array of pillar-type memory devices of claim 13, wherein the array of pillar-type memory devices, further comprising:
a plurality of bottom contacts in a dielectric material, wherein each of the plurality of bottom contacts reside on a portion of a first metal layer below a pillar-type memory device of the plurality of pillar-type memory devices.

15. The array of pillar-type memory devices of claim 13, wherein the second encapsulation material is over the first encapsulation material and the bottom portion of the bump of the conductive material, and wherein the second encapsulation material creates a sloping surface between each of the pillar-type memory devices in the array of pillar-type memory devices to improve interlayer dielectric fill between each of the pillar-type memory devices in the array of pillar-type memory devices.

16. The array of pillar-type memory devices of claim 13, wherein the plurality of pillar-type memory devices in the array of pillar-type memory devices are one of a magnetoresistive random-access memory device, a resistive random-access memory, or a phase change random-access memory device.

17. A method of forming a pillar-type memory device in an array of pillar-type memory devices, the method comprising:
depositing a plurality of layers of materials for forming a pillar for each of a plurality of pillar-type memory devices, wherein a layer of a top electrode material in the plurality of layers of materials forming the pillar is a thin layer of the top electrode material;
patterning the top electrode material;
using an ion beam etch to form each pillar of the plurality of pillar-type memory devices from a plurality of layers of materials;
depositing a layer of an encapsulation material;
etching back the layer of the encapsulation material to expose a top surface of the top electrode material; and
selectively depositing one of a high melting point metal or a metal nitride material on the exposed top surface of the top electrode material to form a conductive bump on the top electrode material.

18. The method of claim 17, further comprising:
depositing a layer of an interlayer dielectric material;
forming a plurality of top electrode contacts in the interlayer dielectric material, wherein each top electrode contact connects to one conductive bump on each top electrode material in the plurality of pillar-type memory devices.

19. The method of claim 17, wherein depositing the plurality of layers of materials for forming the pillar for each of the plurality of pillar-type memory devices, further comprises:
depositing a layer of a bottom electrode material on a layer of a dielectric material surrounding a plurality of bottom electrode contacts;
depositing the plurality of layers of materials to form a magnetic tunnel junction over the layer of the bottom electrode material;
depositing the layer of the top electrode material over a plurality of layers of materials forming the magnetic tunnel junction; and
depositing one or more layers of lithographic material for patterning the layer of the top electrode material.

20. The method of claim 17, wherein etching back the layer of the encapsulation material to expose the top surface of the top electrode material, further comprises depositing a layer of a liquid-based dielectric material using one of a spin-on-dielectric process or a vacuum chemical vapor deposition process, wherein the liquid-based dielectric material covers a bottom portion of the encapsulation material.

21. A method of forming a pillar-type memory device in an array of pillar-type memory devices, the method comprising:
depositing a plurality of layers of materials for forming a pillar for a plurality of pillar-type memory devices in an array of pillar-type devices, wherein a layer of a top electrode material in a plurality of layers of material is a thin layer of the top electrode material;
patterning the top electrode material;
using an ion beam etch to form each pillar of the plurality of pillar-type memory devices from a plurality of layers of materials;
depositing a layer of a first encapsulation material;
etching back the layer of the first encapsulation material to expose a top surface of the top electrode material;
selectively depositing one of a high melting point metal or a metal nitride material on the exposed top surface of the top electrode material to form a conductive bump on the top electrode material;
depositing a layer of a second encapsulation material over the first encapsulation material, over an exposed portion of a dielectric material between each pillar of the plurality of pillar-type memory devices, and surrounding a bottom portion of the conductive bump on the top electrode;
etching back the layer of the second encapsulation material to expose a top surface of the conductive bump; and
depositing an interlayer dielectric material over exposed surfaces of the conductive bump, the second encapsulation material, and the dielectric material between each pillar of the plurality of pillar-type memory devices.

22. The method of claim 21, further comprising:
forming a plurality of top electrodes contact in the interlayer dielectric material, wherein each of the top electrode contacts connects to the conductive bump on each top electrode material in the plurality of pillar-type memory devices.

23. The method of claim 21, wherein depositing the plurality of layers of materials for forming the pillar for the plurality of pillar-type memory devices, further comprises:
depositing a layer of a bottom electrode material on a layer of a dielectric material surrounding a plurality of bottom electrode contacts;
depositing the plurality of layers of materials to form a magnetic tunnel junction over the layer of the bottom electrode material;
depositing the layer of the top electrode material over the plurality of the layers of material for forming the pillar, wherein the pillar includes the magnetic tunnel junction; and
depositing one or more layers of lithographic material for patterning the layer of the top electrode material.

24. The method of claim 21, wherein the conductive bump on the top electrode material is wider than to top electrode material, and wherein the conductive bump is a second portion of the top electrode that increases a height of the top electrode in the plurality of pillar-type memory devices.

25. The method of claim 21, wherein depositing the layer of the second encapsulation material reduces a gap between each pillar in the array of pillar-type devices, wherein the layer of the second encapsulation material improves an interlayer dielectric material gap fill.
